(19) United States
(12) Patent Application Publication
(10) Pub. No.: US 2026/0247576 A1
(43) Pub. Date: Aug. 20, 2026

(54) HEAT SINK ASSEMBLY

(71) Applicant: Aivres Systems Inc., San Jose, CA (US)

(72) Inventor: Chao Chi Shih, Taipei (TW)

(21) Appl. No.: 19/058,695

(22) Filed: Feb. 20, 2025

(51) Int. Cl. H05K 7/20; G06F 1/20

(52) U.S. Cl. CPC H05K 7/2039; G06F 1/20

(57) ABSTRACT

A heat sink assembly includes a base comprising a plurality of retaining portions and a heat sink comprising a plurality of connecting portions extending toward the base. Each of the plurality of connecting portions of the heat sink is adapted to engage with one of the plurality of retaining portions of the base, thereby clamping a heat-generating electronic component between the heat sink and the base. The heat sink and the base are adapted for manual assembly and disassembly without requiring any tools.

### TECHNICAL FIELD

This disclosure is generally related to a heat sink assembly for a heat-generating electronic component.

### BACKGROUND

High-power electronic components require heat sinks to help dissipate waste heat in order to avoid damages. Heat sinks may be categorized as tool-requiring heat sink assemblies and tool-free heat sink assemblies. Typically, tool-requiring heat sink assemblies have more parts and higher costs, and it takes longer to put them together. On the other hand, tool-free heat sink assemblies require a latching mechanism that is appropriately designed to balance the easy of assembly and the sturdiness of the mechanism.

Disclosed herein is a tool-free heat sink assembly, which has a reduced costs since it uses fewer number of parts such as screws.

### SUMMARY

Described herein is a heat sink assembly adapted for manual assembly and disassembly without requiring any tools.

In one general aspect, disclosed herein is a heat sink assembly comprising a base comprising a plurality of retaining portions and a heat sink comprising a plurality of connecting portions extending toward the base. In some embodiments, each of the plurality of connecting portions of the heat sink is adapted to engage with one of the plurality of retaining portions of the base, thereby clamping a heat-generating electronic component between the heat sink and the base. In some embodiments, the heat sink and the base are adapted for manual assembly and disassembly without requiring any tools.

In some embodiments, the heat sink comprises four connecting portions, and the base comprises four retaining portions. In some embodiments, one pair of the connecting portions is a mirror image in shape of the other pair of the connecting portions.

In some embodiments, each of the plurality of retaining portions comprises a protrusion. In some embodiments, each of the plurality of connecting portions comprises a tab and a hole punctured in the tab, and the hole is adapted for receiving the protrusion. In some embodiments, the tab is L-shaped. In some embodiments, the tab is adapted to grasp the base by an elastic force. In some embodiments, the heat sink is adapted to be released from the base when the tab is deformed. In some embodiments, the heat sink is adapted to be released from the base by lift the tab away from the base. In some embodiments, the tab is adapted to elastically retore to its original shape after the tab is momentarily deformed. In some embodiments, the hole is rectangular, circular, or square in shape. In some embodiments, the hole is rectangular in shape. In some embodiments, the protrusion has an asymmetric profile with one side of the protrusion having a smooth gradient, and another side of the protrusion having an abrupt gradient.

In some embodiments, the heat sink assembly further comprises a layer of a plastic heat conducting medium. In some embodiments, the layer of the plastic heat conducting medium is situated between the heat sink and the heat-generating electronic component. In some embodiments, the plastic heat conducting medium is a thermal paste.

In some embodiments, the heat sink assembly does not comprise any screws.

In some embodiments, the heat-generating electronic component is a solid-state drive. In some embodiments, the solid-state drive is an M.2 NVME (NVM Express) solid-state drive. In some embodiments, the heat-generating electronic component is a computer expansion card, adapter card, peripheral, or accessory in an M.2 module.

In some embodiments, the dimensions of the heat sink and the base are adapted for accommodating a solid-state drive in M.2 form factor.

In another aspect, disclosed herein is a heat sink assembly comprising a base comprising four protrusions and a heat sink comprising four tabs extending toward the base. In some embodiments, each one of the four tabs comprises a hole adapted for receiving one of the four protrusions of the base. In some embodiments, the four tabs of the heat sink are adapted to grasp the base elastically, thereby clamping a heat-generating electronic component between the heat sink and the base. In some embodiments, the heat sink assembly is adapted for manual assembly and disassembly without requiring any tools.

In yet another general aspect, disclosed herein is a computer storage module comprising a base comprising a plurality of protrusions, a solid-state drive, and a heat sink comprising a plurality of tabs extending toward the base. In some embodiments, each of the plurality of tabs of the heat sink comprises a hole adapted for receiving one of the plurality of protrusions of the base. In some embodiments, each of the plurality of tabs of the heat sink is adapted to grasp the base by an elastic force, thereby clamping the solid-state drive between the heat sink and the base. In some embodiments, the solid-state drive is a M.2 NVME (NVM Express) solid-state drive.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 shows a heat sink assembly including a heat sink and a base.

FIG. 2 is an exploded view of the heat sink assembly.

FIG. 3 illustrates the connecting portions of the heat sink.

FIG. 4 illustrates the retaining portions of the base.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

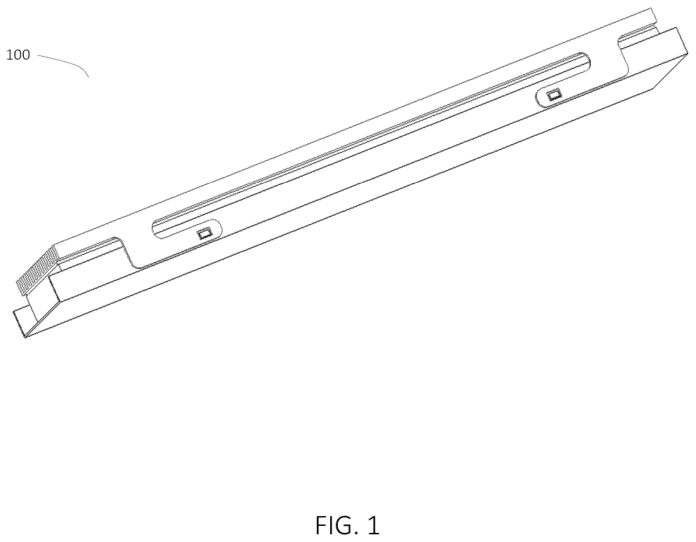

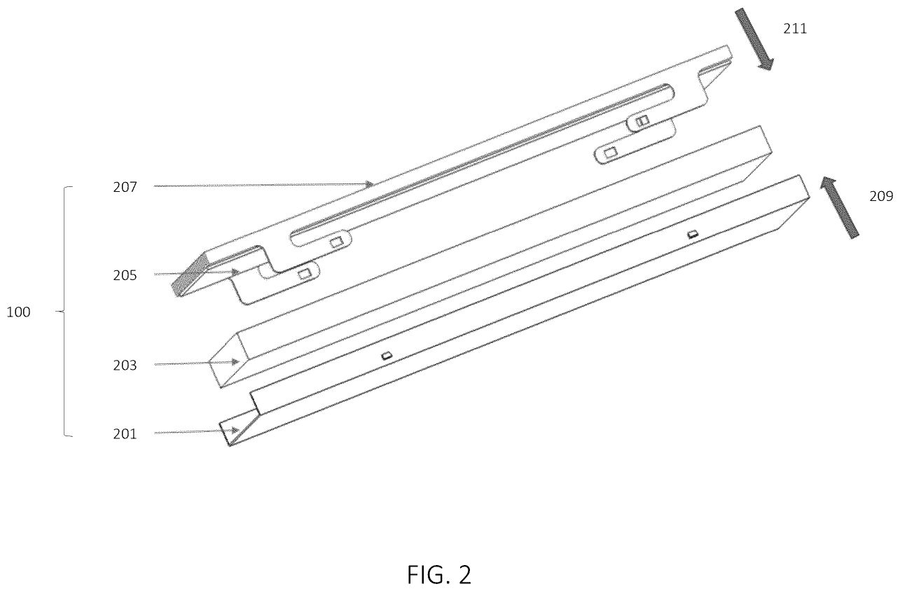

The embodiments will now be explained with the accompanying figures. Reference is first made to FIGS. 1 and 2, which show a heat sink assembly 100. FIG. 1 shows a fully assemble heat sink assembly 100. FIG. 2 shows an exploded view of the heat sink assembly 100, which comprises a base 201, a heat sink 207, and a heat-generating electronic component 203 clamped in between the base 201 and the heat sink 207.

In the embodiment shown in FIG. 2, the heat sink assembly 100 further comprises a layer of a plastic heat conducting medium 205 that is applied at the interface between the heat sink 207 and the heat-generating electronic component 203. In some embodiments, the plastic heat conducting medium 205 is a thermal paste (also known as thermal compound, thermal grease, thermal interface material, thermal gel, heat paste, heat sink compound, heat sink paste, or CPU grease). The function of the thermal paste is to eliminate air gaps or spaces—which act as thermal insulation—from the interface area in order to maximize heat transfer and dissipation.

In some embodiments, the heat sink and the base are adapted for manual assembly and disassembly without requiring any tools. In the embodiment shown in FIG. 2, the heat sink assembly can be assembled together in a “tool-free” manner by manually pressing the base 201 and the heat sink 207 towards each other in the direction indicated by the arrows 209 and 211.

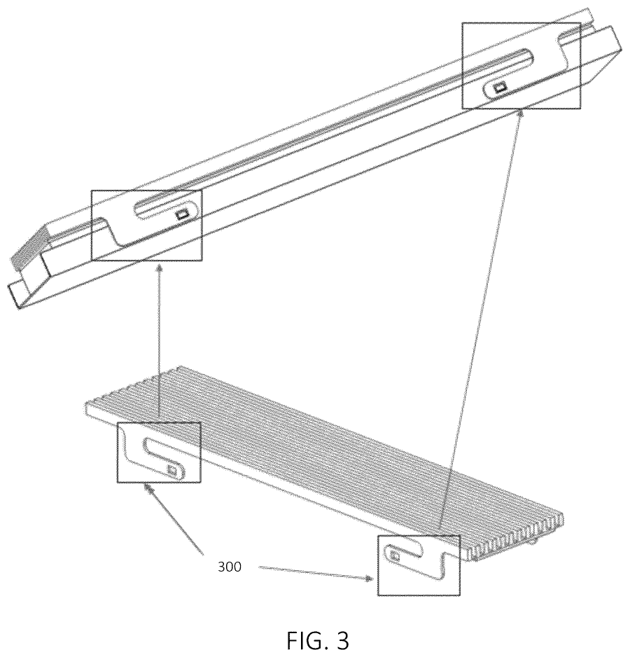

FIG. 3 illustrates the heat sink's connecting portions. In the embodiment shown in FIG. 3, the connecting portions are four “L”-shaped tabs 300 (two are shown and two more are obscured from view). The two tabs shown in FIG. 3 are mirror images of each other in shape and position. Each “L”-shaped tab is connected to the heat sink at one end of the “L,” and has a hole punctured in the tab at the other end of the “L.” The hole may be rectangular, circular, or square in shape. In the embodiment shown in FIG. 3, the hole in each tab is rectangular in shape. The size of hole is adapted for receive a protrusion on the base. In the embodiment shown in FIG. 3, each rectangular hole is sized to fit within it a protrusion on the base.

In some embodiments, each of the tabs is a springy strip of metal and is adapted to grasp the base by its elasticity. When the tabs are pulled away from the base, they are temporarily deformed, and the base is released from the tabs of the heat sink. Afterwards, the tabs spring back to their original positions and shape.

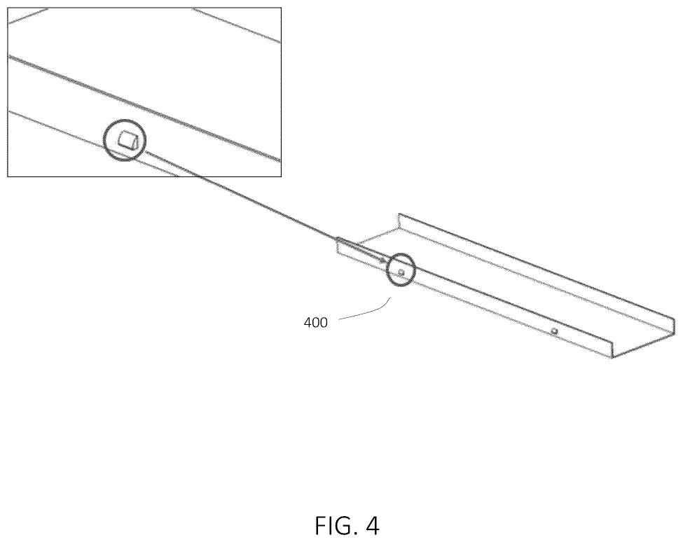

FIG. 4 illustrates the base's retaining portions. In the embodiment shown in FIG. 4, the retaining portions are four protrusions, with two protrusions 400 on one side of the base, and two more protrusions on the opposite side of the base that is obscured from view. In the embodiment shown in FIG. 4, each one of the protrusions 400 has an asymmetric profile: the side of each protrusion facing the heat sink has a shallow gradient and is curved so that its matching tab on the heat sink can glide over it smoothly when the heat sink and the base are pushed together. The side of each protrusion facing away the heat sink has a steep and abrupt gradient so that the protrusion can fall into its matching hole on the heat sink's tab with a “click” when the heat sink and the base are pushed together.

The latching mechanism in the heat sink assembly disclosed herein enables its tool-free assembly by manually pressing together the heat sink, a heat-generating electronic component, and the base for the heat sink. The assembly can also be easily disassembled by lifting the tabs on the heat sink, then pulling away the heat sink from its base. The electronic component is then readily released from the assembly.

This latching mechanism may be used in all electronic products in which tool-free assembly is desired, with increased efficiency of assembly and lower costs.

The foregoing description of the present disclosure has been provided for the purposes of illustration and description. It is not intended to be exhaustive or to limit the disclosure to the precise forms disclosed. The breadth and scope of the present disclosure should not be limited by any of the above-described exemplary embodiments. Many modifications and variations will be apparent to the practitioner skilled in the art. The modifications and variations include any relevant combination of the disclosed features. The embodiments were chosen and described in order to best explain the principles of the disclosure and its practical application, thereby enabling others skilled in the art to understand the disclosure for various embodiments and with various modifications that are suited to the particular use contemplated. It is intended that the scope of the disclosure be defined by the following claims and their equivalence.

What is claimed is:

1. A heat sink assembly comprising:
a base comprising a plurality of retaining portions; and
a heat sink comprising a plurality of connecting portions extending toward the base;
wherein each of the plurality of connecting portions of the heat sink is adapted to engage with one of the plurality of retaining portions of the base, thereby clamping a heat-generating electronic component between the heat sink and the base; and
wherein the heat sink and the base are adapted for manual assembly and disassembly without requiring any tools.

2. The heat sink assembly of claim 1, wherein the heat sink comprises four connecting portions, and the base comprises four retaining portions.

3. The heat sink assembly of claim 1, wherein one pair of the connecting portions is a mirror image in shape of the other pair of the connecting portions.

4. The heat sink assembly of claim 1, wherein each of the plurality of retaining portions comprises a protrusion.

5. The heat sink assembly of claim 4, wherein each of the plurality of connecting portions comprises a tab and a hole punctured in the tab, and the hole is adapted for receiving the protrusion.

6. The heat sink assembly of claim 5, wherein the tab is L-shaped.

7. The heat sink assembly of claim 5, wherein the tab is adapted to grasp the base by an elastic force.

8. The heat sink assembly of claim 7, wherein the heat sink is adapted to be released from the base when the tab is deformed.

9. The heat sink assembly of claim 7, wherein the heat sink is adapted to be released from the base by lift the tab away from the base.

10. The heat sink assembly of claim 8, wherein the tab is adapted to elastically retore to its original shape after the tab is momentarily deformed.

11. The heat sink assembly of claim 5, wherein the hole is rectangular, circular, or square in shape.

12. The heat sink assembly of claim 11, wherein the hole is rectangular in shape.

13. The heat sink assembly of claim 5, wherein the protrusion has an asymmetric profile with one side of the protrusion having a smooth gradient, and another side of the protrusion having an abrupt gradient.

14. The heat sink assembly of claim 1, further comprising a layer of a plastic heat conducting medium.

15. The heat sink assembly of claim 14, wherein the layer of the plastic heat conducting medium is situated between the heat sink and the heat-generating electronic component.

16. The heat sink assembly of claim 14, wherein the plastic heat conducting medium is a thermal paste.

17. The heat sink assembly of claim 1, wherein the heat sink assembly does not comprise any screws.

18. The heat sink assembly of claim 1, wherein the heat-generating electronic component is a solid-state drive.

19. A heat sink assembly comprising:
a base comprising four protrusions, and
a heat sink comprising four tabs extending toward the base;
wherein each one of the four tabs comprises a hole adapted for receiving one of the four protrusions of the base;
wherein the four tabs of the heat sink are adapted to grasp the base elastically, thereby clamping a heat-generating electronic component between the heat sink and the base; and
wherein the heat sink assembly is adapted for manual assembly and disassembly without requiring any tools.

20. A computer storage module comprising:
a base comprising a plurality of protrusions,
a solid-state drive, and
a heat sink comprising a plurality of tabs extending toward the base;
wherein each of the plurality of tabs of the heat sink comprises a hole adapted for receiving one of the plurality of protrusions of the base; and
wherein each of the plurality of tabs of the heat sink is adapted to grasp the base by an elastic force, thereby clamping the solid-state drive module between the heat sink and the base.
